(19) United States
(12) Patent Application Publication
(10) Pub. No.: US 2009/0214787 A1
(43) Pub. Date: Aug. 27, 2009

(54) Erosion Resistant Coatings

(75) Inventors: Ronghua WEI, San Antonio, TX (US); Christopher RINCON, San Antonio, TX (US); Edward LANGA, San Antonio, TX (US)

Correspondence Address: GROSSMAN, TUCKER, PERREAULT & PFLEGER, PLLC, 55 SOUTH COMMERICAL STREET, MANCHESTER, NH, 03101, US

(73) Assignee: SOUTHWEST RESEARCH INSTITUTE, San Antonio, TX (US)

(21) Appl. No.: 12/391,416

(22) Filed: Feb. 24, 2009

Related U.S. Application Data
(63) Continuation-in-part of application No. 11/550,718, filed on Oct. 18, 2006.
(60) Provisional application No. 60/728,425, filed on Oct. 18, 2005.

(51) Int. Cl. C23C 16/448; C23C 16/06

(52) U.S. Cl. 427/255.394; 427/248.1; 427/255.28

(57) ABSTRACT

The present disclosure relates to a method for producing a coating on a substrate. The method may include depositing metal atoms on one or more surfaces of a substrate, subjecting the metal atoms to a reactive gas, and producing a coating layer of a metal compound, wherein the metal compound may include nanocrystals of a transition metal compound in a ceramic matrix, wherein the transition metal compound may be selected from the group consisting of metal nitrides, metal carbides, metal silicides and combinations thereof. The reactive gas may be supplied from a precursor containing silicon, carbon and hydrogen, wherein the precursor may have a MW of greater than or equal to 100.

### CROSS REFERENCE TO RELATED APPLICATIONS

The present application is a continuation in part of U.S. patent application Ser. No. 11/550,718 filed on Oct. 18, 2006, which claims the benefit of the filing date of U.S. Provisional Application Ser. No. 60/728,425 filed Oct. 18, 2005, the teachings of such applications are incorporated herein by reference.

### FIELD OF INVENTION

The present invention relates to erosion resistant coatings including metal compounds having nanocrystalline domains dispersed in a ceramic matrix. The coatings may be produced by plasma enhance magnetron sputtering using a relatively high molecular weight reactive gas.

### BACKGROUND

Components used in rotary machinery such as gas turbine compressor blades of aircraft engines, helicopter rotors and steam turbines, are subject to severe sand erosion, particularly in dusty environments. Coatings have been applied to the blades to protect the blades and provide a degree of corrosion or wear resistance. In some applications, the coatings may include single or multi-layer Ti/TiN coatings of about 25 μm in thickness produced by, for example, cathodic arc or vapor deposition. In other applications, polymeric film may be applied to a leading edge of a blade to provide protection. However, these coatings may not be sufficient and may also be easily eroded or worn away.

### SUMMARY

In one aspect, the present disclosure relates to a method for producing a coating on a substrate. The method may include depositing metal atoms on one or more surfaces of a substrate, subjecting the metal atoms to a reactive gas, and producing a coating layer of a metal compound, wherein the metal compound may include nanocrystals of a transition metal compound in a ceramic matrix, wherein the transition metal compound may be selected from the group consisting of metal nitrides, metal carbides, metal silicides and combinations thereof. The reactive gas may be supplied from a precursor containing silicon, carbon and hydrogen, wherein the precursor may have a molecular weight (MW) of greater than or equal to 100.

In another aspect, the present disclosure relates to a method for producing a coating on a substrate. The method may include depositing metal atoms on one or more surfaces of a substrate, subjecting the metal atoms to a reactive gas, and producing a coating layer of a metal compound, wherein the metal compound may include nanocrystals of a transition metal compound in a ceramic matrix, wherein the transition metal compound may be selected from the group consisting of metal nitrides, metal carbides, metal silicides and combinations thereof. The reactive gas may be supplied from a precursor containing silicon, carbon and hydrogen, wherein the precursor may have a MW of greater than or equal to 100-400 and a vapor pressure of less than 100 mm Hg at 20° C.

In a further aspect, the present disclosure relates to a method for producing a coating on a substrate. The method may include depositing metal atoms on one or more surfaces of a substrate, subjecting the metal atoms to an inert gas and to a reactive gas, and producing a coating layer of a metal and a coating layer of a metal compound, wherein the metal compound may include nanocrystals of a transition metal compound in a ceramic matrix, wherein the transition metal compound may be selected from the group consisting of metal nitrides, metal carbides, metal silicides and combinations thereof. The reactive gas may be supplied from a precursor containing silicon, carbon and hydrogen, wherein the precursor may have a MW of greater than or equal to 100-400 and a vapor pressure of less than 100 mm Hg at 20° C.

### BRIEF DESCRIPTION OF THE DRAWINGS

The detailed description below may be better understood with reference to the accompanying figures which are provided for illustrative purposes and are not to be considered as limiting any aspect of the invention.

FIG. 1 is a schematic of an example of a plasma-enhanced magnetron sputtering system for use in preparing a coating.

FIG. 2 is a schematic of a precursor supply system.

FIG. 3 is a schematic illustrating an example of the morphology of an example of a nanocomposite coating.

FIG. 4 is an example of X-ray diffraction data for the nanocomposite of TiSiCN as prepared on a Ti-6Al-4V substrate using nitrogen and hexamethyldisilazane reactive precursors.

FIG. 5 is an example of X-ray diffraction data for the nanocomposite of TiSiCN as prepared on a Ti-6Al-4V substrate using nitrogen and trimethylsilane reactive precursors.

FIG. 6 is a schematic of an erosion testing set up, wherein erosion testing is performed at an angle α.

FIG. 7 is an illustration of an example of an erosion testing set up.

FIG. 8 is a graph of the erosion rate of various coating compositions developed using hexamethyldisilazane and nitrogen compared to that of uncoated Ti-6Al-4V at both 30° and 90° testing angles.

FIG. 9 is a graph of the erosion resistance improvement of various coating compositions developed using hexamethyldisilazane and nitrogen precursors compared to that of uncoated Ti-6Al-4V at both 30° and 90° testing angles.

FIG. 10 is a graph comparing the wear groove width and depth of uncoated Ti-6Al-4V substrate compared to that of a Ti-6Al-4V substrate covered in a coating as described in example HN-3.

FIG. 11 is a graph comparing the wear rate of various coating compositions developed using hexamethyldisilazane and nitrogen precursors compared to that of uncoated Ti-6Al-4V.

FIG. 12 is a graph comparing the wear resistance improvement of various coating compositions developed using hexamethyldisilazane and nitrogen precursors compared to that of uncoated Ti-6Al-4V.

FIG. 13 is a graph of the coefficient of friction of uncoated Ti-6Al-4V and various coating compositions over a number of cycles measured during ball on disc wear testing.

### DETAILED DESCRIPTION

The present invention relates to an erosion resistant protective coating. The protective coating may include, for example, one or more transition metals in combination with various metalloids deposited over a substrate. The coating may include nanocrystalline domains, which may in some embodiments be dispersed in an amorphous matrix. It may be appreciated that nanocrystalline domains may be understood as domains including some degree of relative atomic ordering, which may form grains having a size in the range of 1 nm to 50 nm or greater, e.g. up to 500 nm, including all values and increments therein. Amorphous may be understood as having little to no relative atomic ordering, wherein any ordering that may be present may be smaller in scale than that of the nanocrystalline domains. The substrate may include engine parts, pipes, or other parts that may be subject to wear and/or corrosion. The substrate may be formed from metals or metal alloys, including titanium, iron, nickel or cobalt based alloys, such as Ti-6Al-4V, stainless steel, etc.

The coating may be produced by a number of methods and systems. Such methods or systems may be adapted to deposit metal atoms onto the surface of the substrate in the presence of reactive gas under conditions effective to produce the desired protective coating. Examples of such systems may include magnetron sputtering systems, arc deposition systems, reactive evaporation systems, arc evaporation systems, sputter chemical vapor deposition systems, reactive magnetron sputtering systems, hollow cathode magnetron sputtering systems, plasma enhanced magnetron sputtering systems, and other suitable systems.

In some embodiments, the coating may be prepared using a conventional magnetron sputtering system. A magnetron may be placed into a vacuum chamber. After the system has been evacuated, an inert gas, such as Ar, may be fed into the system to a pressure of a few millitorrs. A negative voltage, typically several hundred volts, may be applied to the magnetron, generating “magnetron plasma” in front of the magnetron. The negative bias on the magnetron draws ions from the plasma towards the target, thereby resulting in ion sputtering of the target material (Ti, for instance), which may be subsequently deposited onto samples placed downstream of the magnetron, forming a metal deposit (e.g., Ti). If a reactive gas is used, such as nitrogen, then metallic nitrides (e.g., TiN) may be formed.

Using conventional magnetron sputtering, a few variables may be adjusted to control the quality of the coating. For example, the bias voltage on the magnetron can be varied so that the ion energy may be adjusted. However, if the ion energy is too high, atoms of inert gas (typically Ar) may become incorporated into the film, which may cause spallation. Another parameter is the ion-to-atom ratio, which may account for the number of ions that arrive at the surface of the workpieces in order for an atom to be deposited onto the surface of the workpieces. A higher ion-to-atom ratio may lead to a relatively higher quality film, which may be dense and smooth. To increase the ion flux to the sample surface, the power to the magnetron may be increased, but increasing the power to the magnetron may also increase the rate of deposition of metal atoms onto the workpieces. Because of the net increase in deposited metal atoms, the ion-to-atom ratio may not increase proportionately with the ion flux.

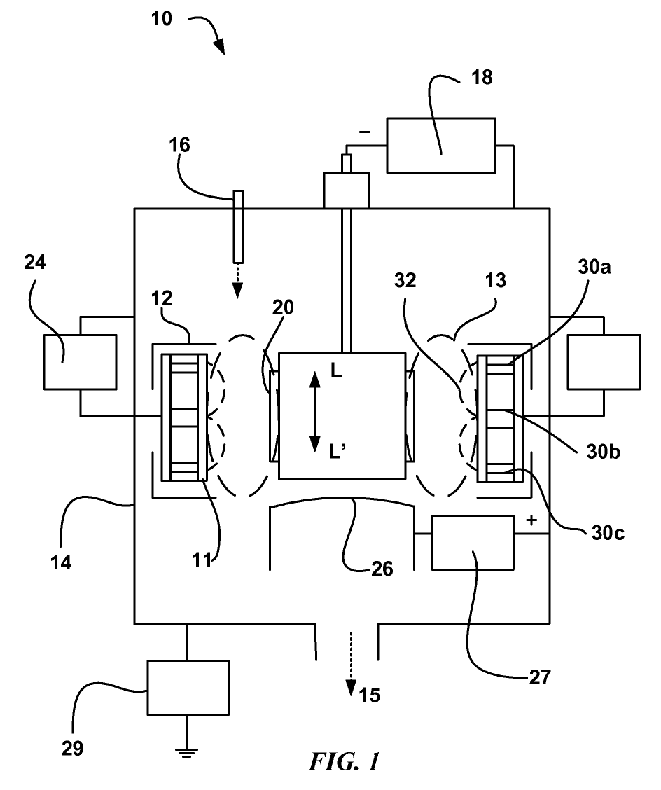

In other embodiments, the coating may be prepared using Plasma Enhanced Magnetron Sputtering (PEMS), an example of which is illustrated in FIG. 1. The magnetron sputtering system 10 may include one or more magnetrons 12, each supporting a sputter material target 11, in a vacuum chamber 14 having a gas port 16 and a pump 15 in fluid communication with the vacuum chamber 14. The gas port 16 may be supplied by precursor supply system, described below, as well as by an inert gas feed.

The magnetron sputtering system may include an electron source 26, such as a filament, which may discharge electrons into the system when heated to thermionic emission temperature. Examples of filaments may include tungsten or tantalum. Electron sources may also include, for example, hollow cathode(s), RF antenna(s) and microwave generator(s). The magnetron sputtering system 10 may provide an energy source 24 for negatively biasing the magnetron 12, an energy source 18 for negatively biasing the surface of the workpieces 20, and an energy source 27 for negatively biasing the electron source, as well as, in some embodiments, an energy source 29 for positively biasing the chamber wall 14. The energy source may be a voltage source and may be associated with circuitry. The energy sources may provide radio frequency (RF) or native voltage in the form of DC power or pulse DC power. Where DC power or pulse DC power may be contemplated, a voltage control may be activated to negatively bias the respective component.

The magnetron 12 may assume any structure or geometry that may be effective to produce a substantially uniform magnetron generated plasma 13 along the length L-L′ of the substrates or workpieces 20. For example, the magnetron may be a planar magnetron, which may be understood as a magnetron that may include one or more permanent magnets aligned adjacent to one another with oppositely orientated poles. The ends of the magnets 30a and 30c may be the north pole of the respective magnet and the end of the adjacent magnet 30b may be the south pole or vice versa. The magnets generate north to south magnetic fields 32, which may be along the length of the sputter target material 11. The magnets may generally produce a magnetic field of 500 Gauss or more, including 1,000 Gauss or more.

The ion current density generated by the magnetron 12 may be relatively uniform along the length of the sputter target material 11. The ion current density generally may be from 0.01 mA/cm² to 500 mA/cm², including all values and increments therein, such as 20 mA/cm². The rate of decay of the sputter target material 11 and the amount of metal atoms deposited onto the surface of the workpieces 20 may be substantially uniform along the length of (L-L′) of the workpieces 20.

Coatings may be produced by a number of methods utilizing the magnetron sputtering system. In some methods, a single coating layer of a nanocrystalline composition may be provided and in other methods multiple coating layers may be provided. It may be appreciated that the multiple coating layers may be alternating layers of a metal and nanocrystalline compositions. In some examples, adhesion layers may be provided and in other examples, the substrates may be sputter cleaned prior to coating.

In one example of a process for forming a coating, the magnetron sputtering system 10 may be evacuated via a pump 15 to a pressure of 10⁻⁶ to 10⁻⁵ torr, including all values and increments therein. An inert gas, which may be understood as a gas that may not be reactive with other compositions may be fed through port 16 and into the vacuum chamber 14. Examples of inert gas may include, but are not limited to, argon, krypton, xenon, etc. Suitable feed rates for each gas delivered may be in the range of 1 to 200 standard cubic centimeters per second (sccm), including all values and increments therein, such as 5 to 50 sccm. The gas may be injected at a pressure of 1 to 10 millitorr including all values and increments therein, and may be continuously fed into the chamber through the duration of the process.

As noted above, the workpiece (or substrate) may be sputter cleaned. Inert gas may be ionized by negatively biasing either the worktable and/or the electron source. When biasing the worktable, a plasma or inert gas ions and electrons may form around the worktable and the ions may be drawn to the negatively biased work table. Biasing the electron source may cause electrons to be ejected into the vacuum chamber, causing collisions with the inert gas, separating the gas into ions and electrons. The ions may again be drawn to the negatively charged worktable. The ions may thus be accelerated towards the workpiece at 50 to 300 eV, including all values and increments therein, to remove surface oxide and/or contaminants. Sputter cleaning may occur for 10 to 200 minutes, including all values and increments therein, such as for 90 minutes.

The magnetron 12 may then be negatively biased at 2 kW or more, such as in the range of 0.05 kW to 10 kW, including all values and increments therein, such as 4 kW to 10 kW, etc., via the energy source 24. The biasing of the magnetron may form a magnetron plasma 34, which may be understood as electrons and gas ions of the inert gas, or other gasses that may be present in the sputtering system 10. Ions from the magnetron plasma 34 may be accelerated toward the sputter target material 11 with sufficient energy to remove or sputter atoms from the target material 11. The sputtered metal atoms maybe deposited onto the surface of the negatively biased workpieces 20 to form a substantially uniform metallic coating having a desired thickness. As used herein, the phrase “substantially uniform coating” may be understood as the surface of the workpieces being covered by a coating of a given thickness. The coating may exhibit a uniformity of thickness of +/−20% or less of the given coating thickness along its length. The sputtered target material may include, for example, one or more transition metals, such as titanium tantalum, hafnium, niobium, vanadium, molybdenum, zirconium, iron, copper, chromium, platinum, palladium, tungsten, and combinations thereof. In addition, the sputtered target material may include a metalloid, such as silicon, boron, aluminum, germanium, lead, bismuth, and indium.

The worktable 22, and thereby the workpieces 20, may be negatively biased at 20 V or more, e.g. up to 200 V, including all values and increments between 20V and 200V therein, such as 200V, 40V, etc., via the energy source 18. The bias of the worktable may draw ions towards the workpiece, which may aide in the densification of the coating. The electron source 26 may also be negatively biased at 50 V or more, e.g. up to 120V, including all values and increments in the range of 50V to 120V, such as 75 V, 120 V, etc., via the energy source 27. The electron source may also provide a current to the worktable of 0.5 A or more, e.g. up to 20 A, including all values and increments in the range of 0.5 A and 20 A, such as 10 A. In addition, a positive charge or bias may be applied to the vacuum chamber wall 14 to aide drawing electrons generated by the electron source towards the wall. The electrons may fill at least a portion of or the entirety of the vacuum chamber and collide with the gas present in the chamber, forming ions and more electrons, as the electrons are accelerated towards the vacuum chamber walls. It may be appreciated that such a positive bias may be developed due to the relative charge of the electrons source and the chamber wall and an energy source may not be necessary to develop the bias.

A reactive gas may also be provided in the chamber through the gas port 16 to participate in the formation of the nanocrystalline compositions, which include a metal compound that may or may not be dispersed in a ceramic matrix prior to or during sputtering. The reactive gas may include one or more precursors, such as a relatively low MW precursor (which may be introduced as a gas) and a relatively high MW precursor (which may be in liquid form and converted to a gas for introduction). Precursors may be understood as a compound or element that may be reacted or combined with another compound or element to form a composition. Examples of relatively low MW precursors that may serve as reactive gasses may include nitrogen, methane, acetylene, oxygen, ammonia or combinations thereof. Such precursors may typically have a MW of less than 100.

The relatively high MW precursors herein may include elements of silicon, carbon and hydrogen. Such precursors may have a MW of 100 or greater, e.g., a MW of 100-400, including all values and increments therein in increments of 1.0. In addition, such precursors may have vapor pressures of less than 100 mm Hg at 20° C. More specifically, they may have vapor pressures of 1-100 mm Hg at 20° C., at 1 mm Hg increments. For example, the relatively high MW precursors may have vapor pressures of 10-30 mm Hg at 20° C. Vapor pressure may be understood as the pressure of a vapor in equilibrium with its non-vapor phases at a given temperature.

Examples of precursors with relatively high MW that may serve as reactive gasses may include silicon containing compositions, such as silanes, siloxanes, silazanes and combinations thereof. The silicon compounds may be alkyl substituted compounds, such as methyl substituted compounds. Accordingly, the relatively high molecular weight precursors may include elements of silicon, carbon and hydrogen, optionally with the presence of nitrogen and/or oxygen.

Expanding upon the above, the precursor trimethylsilane (TMS) is a gas at room temperature and atmospheric pressure, indicating a MW of 74, a melting point of −136° C., a boiling point of 6.7° C. and a vapor pressure of 1200 mm Hg at 20° C. While utilized in certain plasma systems, is relatively expensive and prone to the formation of SiO₂ and result in uncontrollable deposition. Accordingly, to the extent that a silicon based compound is desired, the use of the silicon compounds here provide compounds that are relatively safer to handle, the ability to provide silicon as a component of the ceramic network for nanocrystalline metallic domains, and a relatively less expensive route to the herein coatings without the problems associated with the use of TMS.

Specific examples of silicon compounds herein may include hexamethyldisiloxane, hexamethyldisilazane and/or hexamethyldisilane. The formula for hexamethyldisiloxane may be understood as follows.

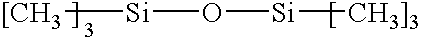

Hexamethyldisiloxane indicates a MW of 162.4, a melting point of −59° C., a boiling point of 101° C. and a vapor pressure of 15 mm Hg at 20° C.

The formula for hexamethyldisilazane may be understood as follows.

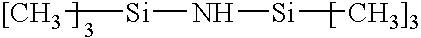

Hexamethyldisilazane indicates a MW of 161.4, a melting point of −70° C., a boiling point of 125° C. and a vapor pressure of 20 mm Hg at 20° C.

The formula for hexamethyldisilane may be understood as follows.

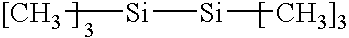

Hexamethyldisilane indicates a MW of 146.4, a melting point of 15° C., a boiling point of 113° C. and a vapor pressure of 30 mm Hg at 25° C.

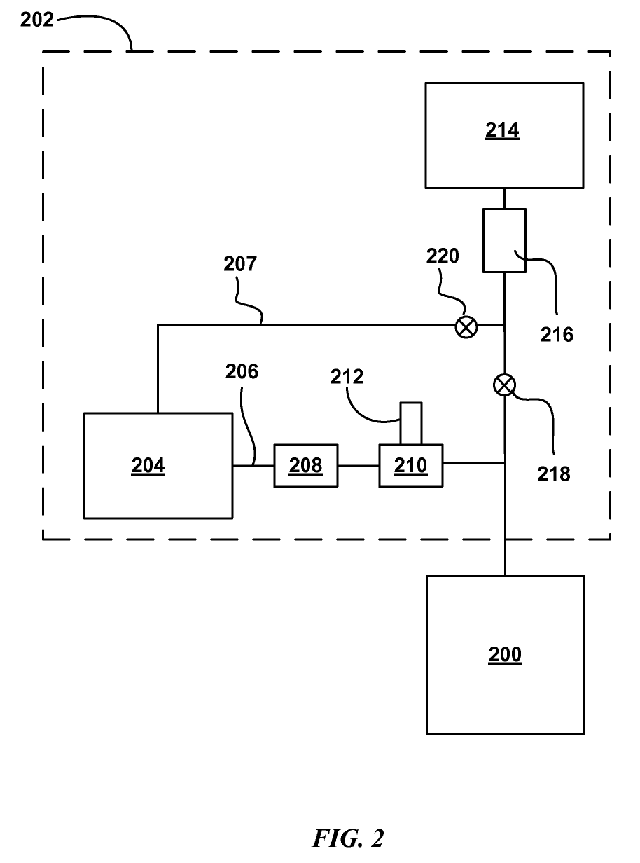

The reactive gas or relatively high molecular weight precursor may be provided to the process chamber 200 via a precursor supply system 202, an example of which is illustrated in FIG. 2. The precursors may be loaded into a container or vessel 204. The container may be in fluid communication with the process chamber by, for example, tubings 206. A mass flow controller 208 may be placed between the container and the process chamber to measure and/or control the flow of the precursors. In addition, a purging system 210 and process may be used to remove air from the precursor supply system. For example, in one embodiment, a vacuum port 212 may be provided to apply vacuum to the precursor supply system. The system, including the precursor container, the mass flow controller and/or tubings, may be heated to a temperature in the range of 27° C. to 60° C., including all values and increments therein, such as 30° C. to 50° C. It may be appreciated that the inert gas supply 214 may tie into the precursor system or may operate separately from the precursor supply system. In such a manner, the inert gas supply 214 may also incorporate a mass flow controller 216 to measure and/or control the flow of the precursors as well as valve 218 to control the flow of the inert gas. In addition, the inert gas from the inert gas supply 214 may be used to carry the reactive gas from the reactive gas/precursor container 204 to the process chamber 200. The inert gas supply may communicate and/or be regulated through valve 220 and tubings 207 to the precursor container 204.

The reactive gas may be provided at a flow rate in the range of 0.1 to 200 standard cubic centimeters per minute (sccm). It may be appreciated that one or more gas precursors may be provided having a flow rate in the range of 0.1 to 100 sccm, including all values and increments therein and one or more relatively high molecular weight precursors may be provided having a flow rate in the range of 0.1 to 200 sccm, including all values and increments therein. In one example, a relatively low molecular weight precursor may include nitrogen provided at a flow rate of 50 sccm and a relatively high molecular weight precursor may include hexamethyldisilazane provided at a flow rate of 0.1 to 50 sccm. Furthermore, as noted above, a number of coatings may be deposited, wherein some of the coating layers may utilize a reactive gas and some of the coating layers do not. The reactive gas flow may again be controlled by, for example, the mass flow controller in such situations. Furthermore, the reactive gas may be mixed with the inert gas during delivery of the gasses to the vacuum chamber, forming a mixed gas.

Once again, the electron source 26 may inject electrons into the vacuum chamber 14. The bias on the workpieces 20, including the deposited metal atoms, may draw injected electrons into the vacuum chamber 14 where the electrons may collide with atoms of the gas. The high energy collisions may cause ionization and production of “electron generated plasma” in substantially the entire vacuum chamber with a large volume. As a result, a number of electron generated plasma ions may bombard the surface of the workpieces 20 comprising the deposited metal atoms, producing the protective coating including the reaction product of the metal atoms and the reactive gas. The electron discharge conditions may be effective to induce the reactive gas to react with the metal atoms to form the desired coating. The electron discharge conditions may generally include a temperature of 200° C. or higher, e.g. up to 500° C., including all values in the range of 200° C. and 500° C. and increments therein.

As noted above, the discharge current of the electron source may be independently controllable, which may allow for increasing the ion-to-atom ratio. The “ion-to-atom ratio” may be defined as the ratio of each arriving ion to the number of metal atoms present at the surface of the substrates or workpieces. The required ion-to-atom ratio may vary according to the mass and energy of the ion species. In some examples, the ion-to-atom ratio may be at least 0.01 ions for every metal atom present at the surface of the substrates or workpieces.

The increase in ion-to-atom ratio produced using an electron source may be reflected in an increase in current (A) to the worktable 22. The electron source may be operated at a discharge current which may be effective to increase the current to the worktable compared to the current to the worktable produced under the same condition in the absence of the electron source. The electron source may be operated at a discharge current effective to produce a current to the worktable 22 which may be five times greater or more, including all increments or ranges there, such as 8 times greater or more, 10 times greater or more, etc., relative to the current to the worktable 22 produced in the absence of the electron source. Suitable discharge currents may vary with the desired ion-to-atom ratio, but generally may be 1 A or more, e.g. up to 20 A, including all ranges and increments therein such as 10 A, depending on the size of the vacuum chamber and the total surface area of the workpiece(s) 20.

For example, at an Ar pressure of 3 millitorr with a Ti target of 6.75″ in diameter and operated at 4 kW, the current to the worktable of 4″×4″ may be about 0.02 A without the electron-generated plasma. In contrast, under the same magnetron condition, with a discharge current of 10 A at the DC power supply between the electron source and the chamber wall, the current to the worktable may be 0.4 A, an increase of about 20 times. The increase in ion-to-atom ratio may increase the coating quality, forming ultra-thick coatings with excellent adhesion to the substrate.

The deposition process may be continued for a period of time sufficient to form a substantially uniform protective coating having a desired thickness. The coating thickness may be 10 μm (micrometers) or more, including all values and increments in the range of 10 μm to 50 Mm, including all values and increments therein, such as 25 μm to 35 μm, as measured by scanning electron microscope (SEM) calibrated using National Institute of Standards and Technology (NIST) traceable standards. The coating thickness may also be measured by other suitable methods, for example, stylus profilometer measurement. The deposition time period required to achieve such thicknesses may generally be 3 hours to 7 hours, including all values and increments therein, such as 4 hours to 6 hours.

As alluded to above, the coatings may be deposited in multiple layers using PEMS, wherein the source of the metal atoms may be a solid metal and the reactive gas may be alternated periodically between inert gas and a reactive gas or a mixed gas including both inert gas and a reactive gas. For example, the magnetron sputtering system 10 may be initially evacuated via the pump 15 to a pressure in the range of 10⁻⁶ to 10⁻⁵ torr, including all values and increments therein. Inert gas may be fed through the gas port 16 and into the vacuum chamber 14, at a rate from 150 sccm and a pressure in the range of 1 to 10 millitorr. The gas may be substantially continuously fed into the chamber through the duration of the process.

In order to deposit a metallic base layer, the magnetron 12 may be negatively biased at 2 kW or more, e.g. up to 10 kW including all values and increments therein, such as 2.7 kW, via the energy source 24. The worktable 22, and the workpieces or substrates 20, may be negatively biased from 20V or more, e.g. to 200 V, including all increments and values therein, such as 40V, via the energy source 18. The electron source 26 may be negatively biased at 50 V or more, e.g. to 120 V, including all values and increments therein such as 75 V, via the energy source 27 to provide a current to the worktable of 1 A or more, e.g. to 20 A, including all values and increments therein, such as 11 A. Ions from the magnetron plasma may be accelerated toward the sputter target material 11 with sufficient energy to remove or sputter atoms from the target material 11.

The sputtered metal atoms may be deposited onto the surface of the negatively biased workpieces 20 under electron discharge conditions effective to form a substantially uniform metallic layer having a desired thickness. The thickness of the metallic layer may be in the range of 0.5 μm to 10 μm, including all values and increments therein, such as 1 μm. The electron discharge conditions may be maintained in the range of 10 to 60 minutes, including all values and increments therein.

Either initially, or once a metallic layer having a desired thickness is formed, one or more reactive gases may be introduced into the chamber. The gasses may include mixed gas, reactive gas and inert gas. The workpieces may then be exposed to electron discharge conditions effective to produce a nanocrystalline metal compound layer having a desired thickness in the range of 1 μm to 25 μm, including all values and increments therein, such as 5 μm. The electron discharge conditions may be maintained for a period in the range of 10 to 60 minutes, including all values and increments therein. The temperature may be maintained at 200° C. or more, e.g. to 500° C., including all values and increments therein, such as 350° C.

After 10 to 60 minutes, the flow of reactive gas may be stopped, and the entire procedure may be repeated until a multilayer protective coating having a given thickness is produced. Suitable multilayer coatings may have a thickness in the range of 10 μm to 200 μm, including all values and increments therein, such as 25 μm to 100 μm, as measured by SEM. The total time period required to achieve such thicknesses may be 2 hours or more, e.g. up to 12 hours, including all values and increments therein, such as 6 hours to 8 hours.

Upon completion, the coated workpieces 20 may be removed from the vacuum chamber 14. The properties of the protective coatings may be evaluated and/or described by a number of procedures, such as by sand erosion tests and various hardness quantifiers.

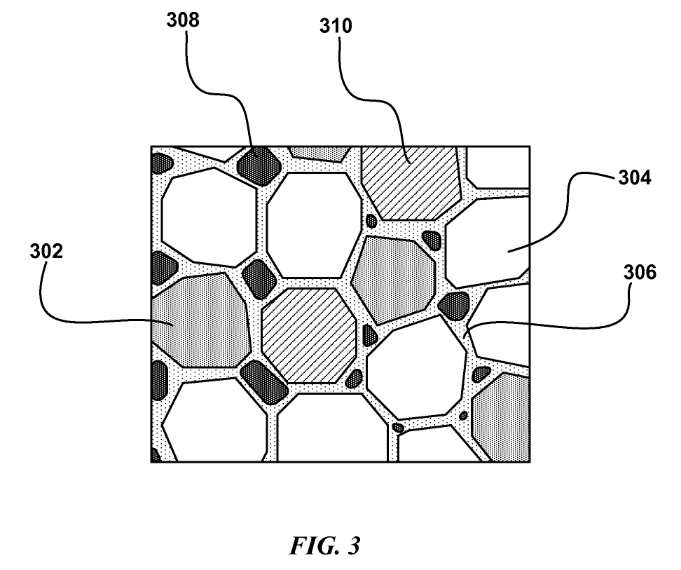

The resulting nanocomposite coatings, illustrated in FIG. 3, may include metal compounds such as metal carbide nanocrystals 302, metal nitride nanocrystals 304, metal silicide nanocrystals 308, and/or metal carbonitride nanocrystals 310, which may be embedded in an amorphous ceramic matrix 306. The metal compounds may include nanocrystals of a transition metal compound. As noted above, the nanocrystals may exhibit a grain size in the range of 1 nm to 50 nm, including all values and increments therein. In one embodiment, the amorphous matrix 306 may be a ceramic which may include an inorganic non-metallic material. In the context of the present disclosure, the relatively high molecular weight silicon precursors herein conveniently provide one source gas component for the formation of the ceramic amorphous matrix, which may include SiN or SiCN compounds.

The nanocrystals 304, 306 may have a grain size of greater than 2 nm, and may be, e.g. from 2 nm or greater, including all values and increments therein, such as in the range of 2 nm to 100 nm, 5 nm to 20 nm, etc. Where an amorphous matrix is not present, the crystals may exhibit a grain size of greater than 100 nm. As noted above, the amorphous matrix may include the reaction product between nitrogen, carbon and combinations thereof, and optionally with an element such as silicon, germanium and combinations thereof.

The resultant protective coating in its entirety may have the formula MSiCₓN_{y}, wherein M is a transition metal and x and y independently are from 0 to 1.5. M, for example, may be titanium, and the protective coating may include nanocrystals of titanium nitride and/or titanium carbonitride embedded in amorphous SiCₓN_{y}. As alluded to above, the nanocomposite coatings may also include a multilayer structure including alternating layers of metal compound and metal. The multilayer nanocomposite may include a base layer, which may be immediately adjacent to the surface being coated. The base layer may be a metallic layer or a metal compound layer. The nanocomposite metal compound layer may be harder than the metal layer, and may include a reaction product of metal one or more elements such as silicon, carbon, nitrogen and combinations thereof. The multilayer structures may have improved fracture toughness and resistance to fatigue cracking compared to monolithic coatings.

The protective coating may be measured by sand erosion tests, wherein the cumulative weight loss may be measured. Sand erosion tests may include any number of cycles of exposure to pressurized particles having a variety of sizes and compositions at a variety of pressures and incident angles for a variety of time periods per cycle. In one embodiment, the sand erosion tests may use alumina particles having an average grain size of 50 μm for 10 cycles of sandblasting at 80 psi at an incident angle of 30° or 90° for 10 seconds per cycle. In such tests, the protective coatings may produce a decrease in cumulative weight loss compared to the bare substrate of 0.5% or more, including all values and increments in the range of 0.5 to 525%, as measured using a microbalance on Ti-6Al-4V substrates.

The coating may be measured by weighing the coated sample with a microbalance while the sand used may be calibrated using a beaker. The abrasive flow rate may be determined by weighing the beaker before and after the sand may be blown in under the expected test conditions for the expected sand flow duration. The microbalance may have an accuracy of about 10 micrograms or less.

The Vickers Hardness exhibited by the coatings may be in the range of 1000 kgf/mm² to 3500 kgf/mm². Vickers Hardness may be understood as a method for measuring the hardness of metals, particularly those with relatively hard surfaces. In one embodiment, the surface may be subjected to a standard pressure for a standard length of time by means of a pyramid-shaped diamond. The diagonal of the resulting indentation may be measured under a microscope and the Vickers Hardness value read from a conversion table.

Furthermore, the coatings may exhibit an increased wear resistance over the substrate. The wear resistance may be measured as a wear rate, which in some examples, may be evaluated using a ball-on-disc tribometer, wherein the ball may have a given diameter and may be applied with a given load around a wear track of a given diameter. For example, when the ball-on-disc tribometer is set in dry sliding wear mode, the coatings may exhibit a wear rate of 0.5 to 3×10⁻⁹ mm³/N/m using a 6 mm in diameter alumina ceramic ball applied under a load of IN over a wear track diameter of 2 in an ambient environment having humidity of 50-60% over 5,000 cycles. In addition, the coefficient of friction may be reduced as compared to that of the substrate, particularly where the coatings include silicon. For example, the exhibited coefficient of friction may be in the range of 0.25 to 0.3 for coatings that include silicon.

The following examples are presented for illustrative purposes only and are not meant to limit the scope of this application.

### Example 1

Ti-6Al-4V substrates were coated with various compositions using PEMS and a reactive gas including both relatively low molecular weight precursors and relatively high molecular weight precursors. The substrates were sputtered clean with Ar ions at 120 eV for 90 minutes to remove the surface oxide and contaminants. After sputter cleaning, a thin layer of Ti was deposited to increase adhesion between the substrate and coating. The coating took 10 to 20 minutes and the resultant coating thickness was 1-2 μm. Then the various TiSiCN coatings were deposited on the samples under the conditions described in the following tables. The deposition was performed for four to five hours and, as can be seen in the tables below, the flow rates of HMDSN were adjusted while the flow of Nitrogen (N₂) was maintained at 50 sccm.

| | Sputter | | | | Bias | |
|---|---|---|---|---|---|---|
| Sample | Time | Deposition | Discharge | Discharge I | V | Bias I |
| No. | (min) | Time (min) | V (V) | (A) | (V) | (A) |
| HN-1 | 90 | 4 | 120 | 4.8 | 80 | 0.96 |
| HN-2 | 90 | 4 | 120 | 5.6 | 80 | 0.90 |
| HN-3 | 90 | 4 | 120 | 5.6 | 80 | 1.02 |
| HN-4 | 90 | 4 | 120 | 5.4 | 80 | 0.93 |
| HN-5 | 90 | 4 | 120 | 5.4 | 80 | 0.80 |
| HN-6 | 90 | 5 | 120 | 5.4 | 80 | 0.80 |

| | Q HMDSN | Q N₂ | Thickness | Deposit | |
|---|---|---|---|---|---|
| Sample No. | (sccm) | (sccm) | (μm) | Rate | Comments |
| HN-1 | — | 50 | 29.3 | 7.3 | Single Layer |
| HN-2 | 15 | 50 | 22.7 | 5.7 | Single Layer |
| HN-3 | 10 | 50 | 28.5 | 7.1 | Single Layer |
| HN-4 | 5 | 50 | 20.5 | 5.1 | Single Layer |
| HN-5 | 8 | 50 | 20.0 | 5.0 | Single Layer |
| HN-6 | 20 | 50 | 36.2 | 7.2 | TiSiCN/ |
| | | | | | Ti/TiSiCN |

As noted above, the discharge voltage was 120 V, while the discharge current was maintained by adjusting the filament emission. In addition, a negative bias was applied to the parts and as described above the bias voltage was 80 V and the total current drawn to the work table was from 0.8 to 1.05 A. Furthermore, the coatings applied on samples HN-1 through HN-5 were single layer coatings, whereas the coating applied to sample HN-6 is a multilayer coating.

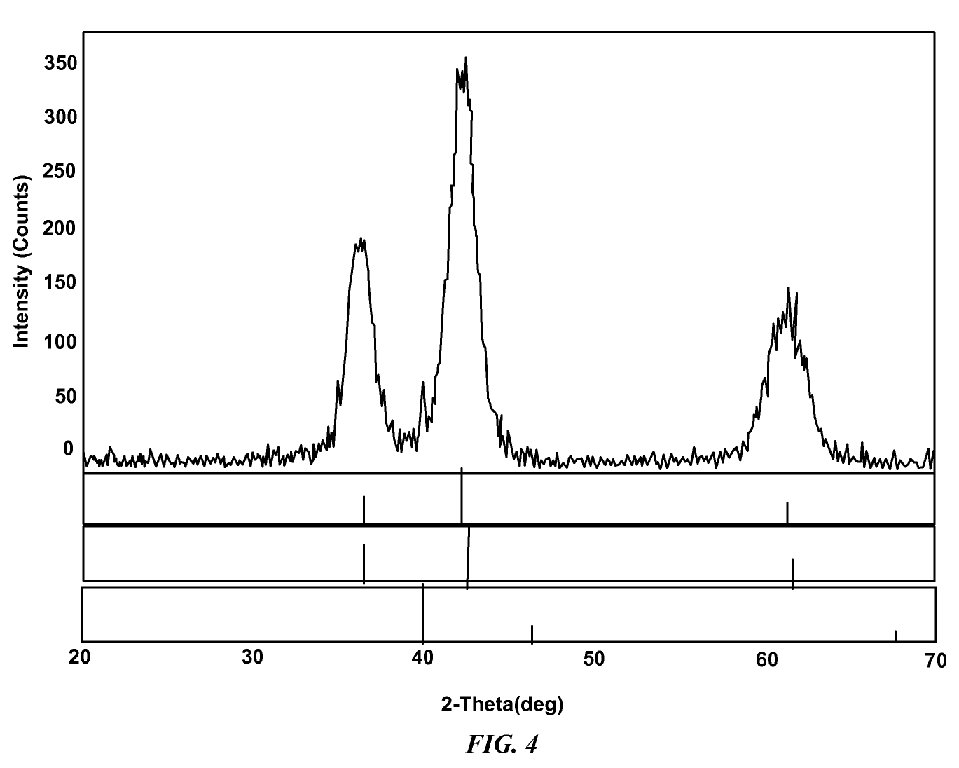

The samples were measured using energy dispersive spectroscopy (EDS) to obtain the coating compositions. In addition, X-ray diffraction (XRD) was performed to obtain the micro-structure of the compositions, an example of which is illustrated in FIG. 4 for HN-2. The results of the EDS and XRD results are described in the table below. It is noted that the amounts of Ti, Si, C and N are presented.

| Sample No. | Ti | Si | C | N | Grain Size (nm) |
|---|---|---|---|---|---|
| HN-1 | 51.5 | — | 7.5 | 41.0 | >100 |
| HN-2 | 35.3 | 4.8 | 33.9 | 26.0 | 5.5 |
| HN-3 | 45.4 | 1.0 | 17.8 | 35.8 | >100 |
| HN-4 | 42.0 | 2.1 | 21.0 | 35.0 | 7.0 |
| HN-5 | 34.1 | 4.0 | 32.0 | 30.1 | 5.1 |
| HN-6 | 6.5 | 15.6 | 65.7 | 12.3 | 15.7 |

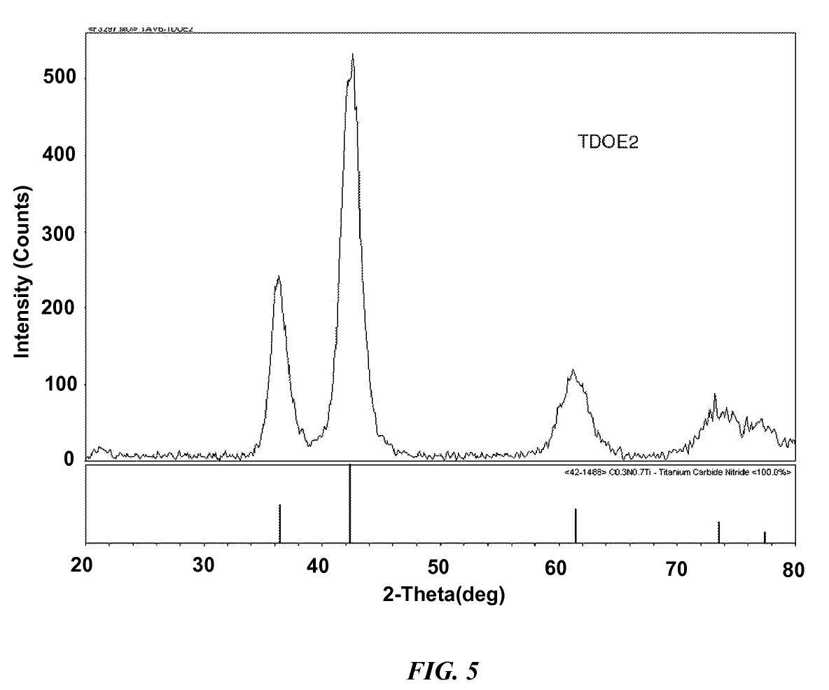

As can be seen from the above, the coatings included Si at a concentration of 1 to 16 atomic percent, which may similarly be found when using trimethylsilane gas as a reactive precursor. In addition, the XRD data is also similar to the spectra obtained for coatings using TMS, an example of which is illustrated in FIG. 5. The sample prepared using TMS were prepared over a Ti-6Al-4V with nitrogen, TMS and argon mixed gas.

In addition, hardness, erosion and wear testing were performed on the compositions. The hardness testing was performed by Vicker's microhardness measured at a 25 gram load. The results are illustrated in the table below.

| Sample No. | Hv (kgf/mm²) |
|---|---|
| HN-1 | 1279.2 |
| HN-2 | 1709.0 |
| HN-3 | 1584.0 |
| HN-4 | 3397.0 |
| HN-5 | 2729.8 |
| HN-6 | 1391.0 |

It is noted that when Si is present at 2.1 at % and the grain size is 7 nm, the hardness is about 3400 kgf/mm², which is similar to coatings obtained using trimethylsilane as a precursor.

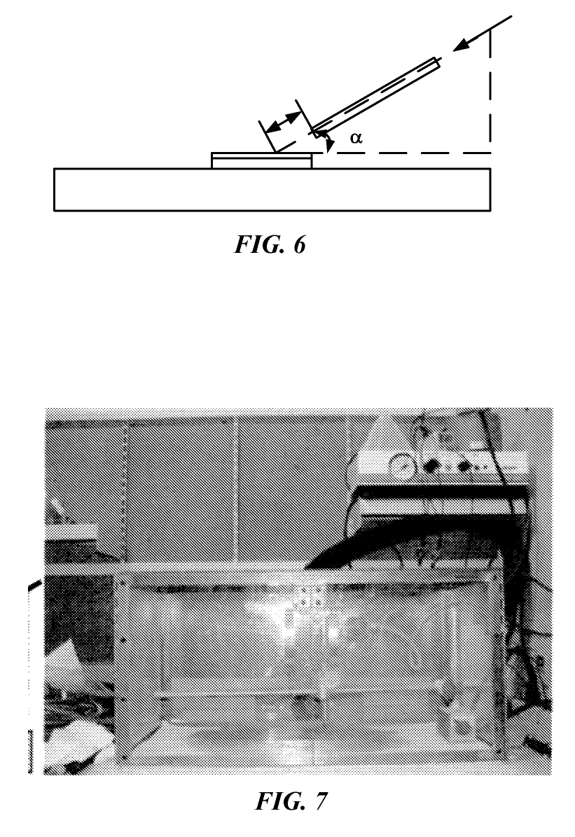

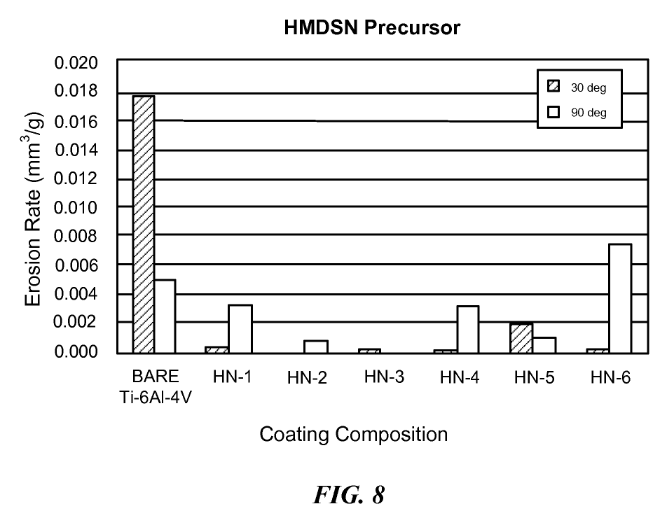

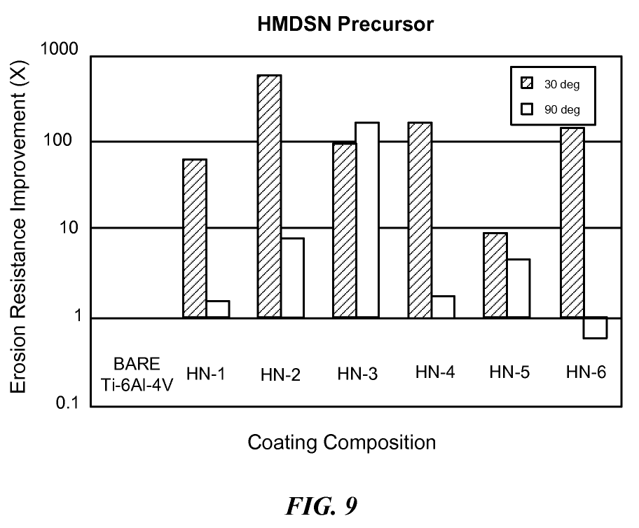

Erosion testing was performed using a micro sand blaster, as shown in schematically in FIG. 6 and depicted in FIG. 7. During erosion testing 50 μm Al₂O₃ test media was used and the back pressure on the nozzle set at 20 psi. The testing duration for blasting was 2 minutes and two incident angles at 30° and 90° were examined. The samples were weighed before and after testing. Bare Ti-6Al-4V was also tested to provide a comparison. In addition, the erosion resistance improvement was calculated using the erosion rate of the bare sample divided by that of the coated data. The results of the testing are illustrated in the table below and the erosion rate and erosion resistance improvement is plotted in FIGS. 8 and 9, respectively.

| | | Erosion | Erosion | Erosion |
|---|---|---|---|---|
| | Erosion Rate | Rate | Resistance | Resistance |
| | 30 deg | 90 deg | Improvement | Improvement |
| Sample No. | (mm³/g) | (mm³/g) | 30 deg (X) | 90 deg (X) |
| HN-1 | 0.0003 | 0.0033 | 56.2 | 1.0 |
| HN-2 | 0.000035 | 0.0006 | 506.2 | 7.8 |
| HN-3 | 0.0002 | 0.0000 | 84.4 | 141.0 |
| HN-4 | 0.0001 | 0.0030 | 168.7 | 1.6 |
| HN-5 | 0.0019 | 0.0011 | 9.4 | 4.5 |
| HN-6 | 0.0001 | 0.0075 | 126.6 | 0.7 |
| Bare Ti—6Al—4V | 0.0176 | 0.0049 | 1.0 | 1.0 |

As can be seen from the above, the erosion resistance of the samples including the various coatings is greater than the bare uncoated substrate.

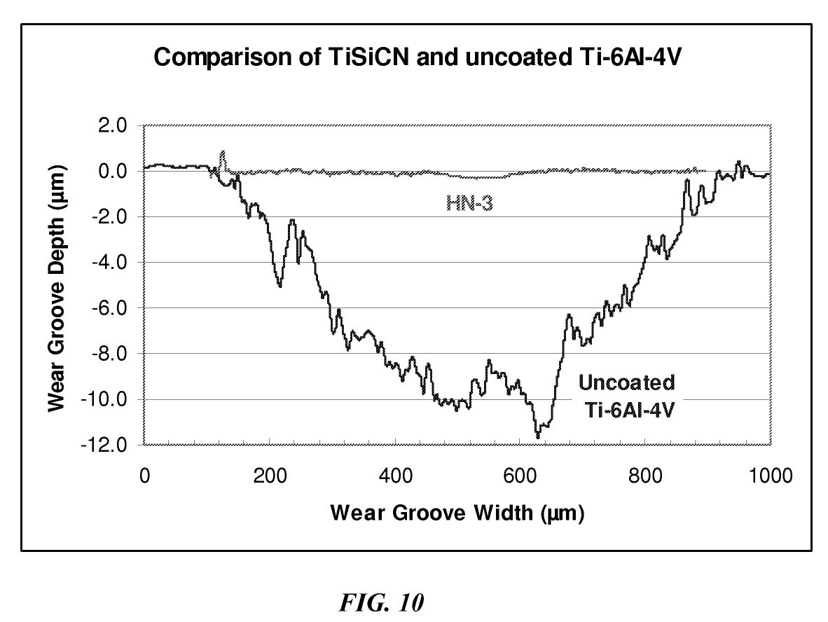

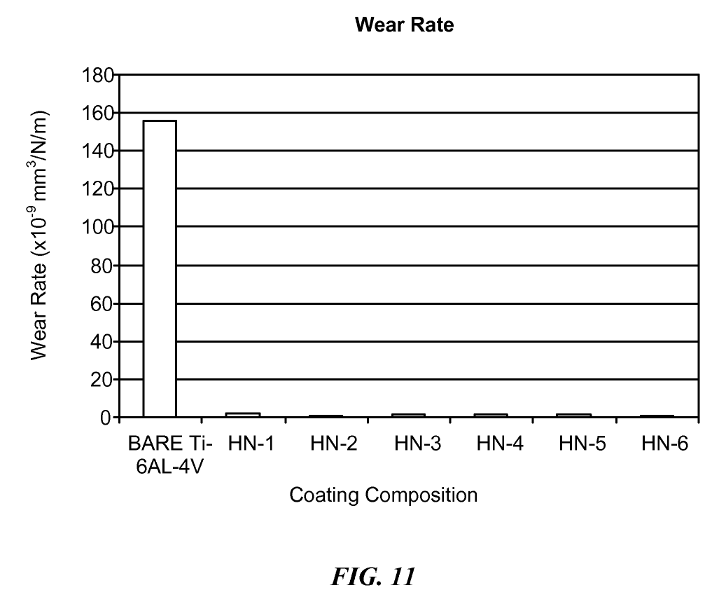

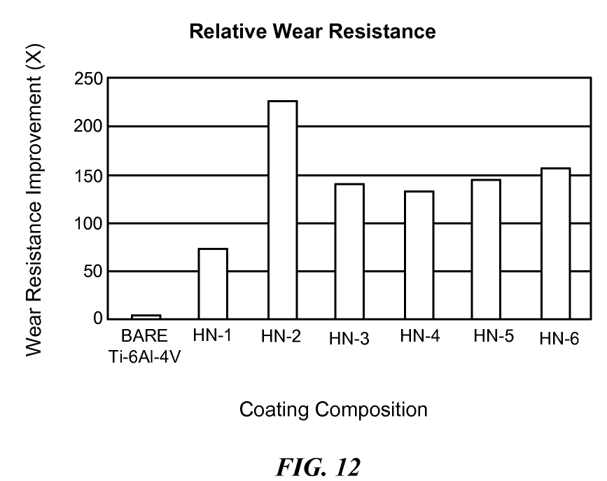

The wear resistance and friction properties of the coatings were evaluated using ball-on-disc tribometer. An alumina ceramic ball of 6 mm in diameter was used with an applied load of 1 N and a wear track diameter of 2 cm. The disc rotated at 100 rpm in dry sliding wear mode, in an ambient environment where the humidity was 50-60 percent. A total of 5,000 cycles of sliding was conducted. The friction history was recorded and after testing the wear groove was measured using a profilometer (Dektak 150) and the wear rate calculated. The results of the testing are shown in the table below. FIG. 10 illustrates wear grooves for the bare uncoated Ti-6Al-4V and HN3 samples. As illustrated in the Figure, the wear groove of the coated sample is much smaller in depth and width than that produced in the uncoated Ti-6Al-4V sample. The wear rate was calculated by integrating the wear groove area and the sliding distance, which is listed in the below table and illustrated in FIG. 11 for each coating. Furthermore, the wear resistance improvement factor was calculated by comparing (dividing) the wear rate for the bare substrate with that of the coated substrates. The data is also presented in the below table and illustrated in FIG. 12. As can be seen, the nanocomposite coatings increased the wear resistance of the bare substrate a few hundred times.

| | Wear Rate | Wear Resistance |
|---|---|---|
| Sample No. | (×10⁻⁹ mm³/N/m) | Improvement (X) |
| HN-1 | 2.2 | 71.2 |
| HN-2 | 0.7 | 227.4 |
| HN-3 | 1.1 | 139.6 |
| HN-4 | 1.2 | 132.7 |
| HN-5 | 1.1 | 144.4 |
| HN-6 | 1.0 | 156.0 |
| Bare Ti—6Al—4V | 155.7 | 1.0 |

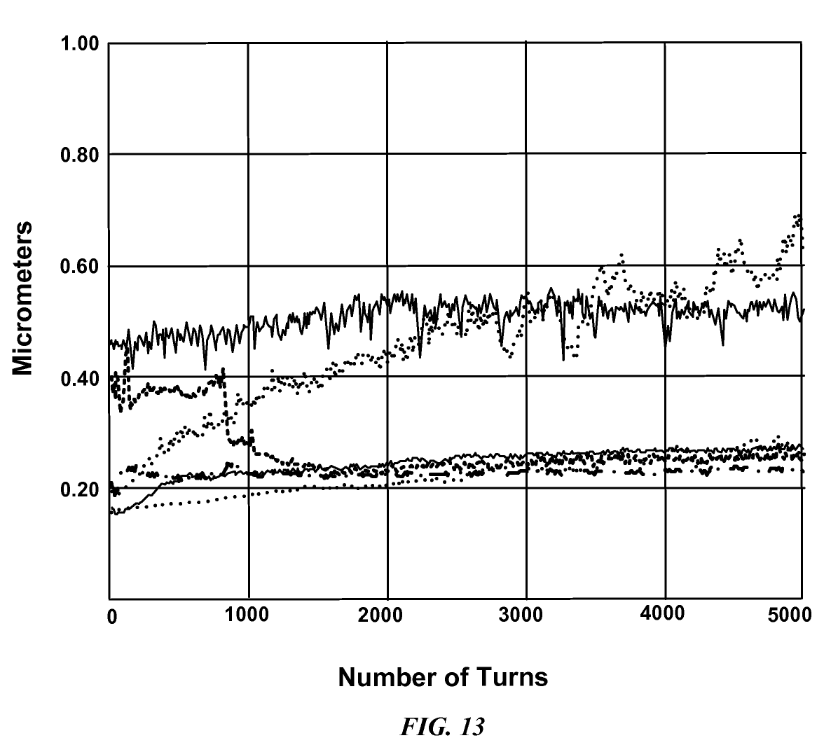

FIG. 13 illustrates the coefficient of friction of the coatings as the testing proceeded. As can be seen in the Figure, the coefficient of friction is about 0.5 for the uncoated Ti-6Al-4V samples, whereas many of the nanocomposite, i.e., HN2-HN-6 coatings reduced the coefficient of friction to 0.25 to 0.29 by 5500 cycles. HN-1 includes no Si and, being a TiN coating, exhibits a coefficient of friction similar to that of the bare substrate ranging from 0.2 at the beginning of testing to 0.7 at the end of testing.

The foregoing description is provided to illustrate and explain the present invention. However, the description hereinabove should not be considered to limit the scope of the invention set forth in the claims appended here to.

What is claimed is:

1. A method for producing a coating on a substrate comprising:
depositing metal atoms on one or more surfaces of a substrate;
subjecting said metal atoms to a reactive gas, said reactive gas supplied from a precursor containing silicon, carbon and hydrogen, said precursor having a MW of greater than or equal to 100; and
producing a coating layer of a metal compound, wherein said metal compound comprises nanocrystals of a transition metal compound in a ceramic matrix, wherein said transition metal compound is selected from the group consisting of metal nitrides, metal carbides, metal silicides and combinations thereof.

2. The method of claim 1, wherein said precursor has a MW of 100-400.

3. The method of claim 1, wherein said precursor has a vapor pressure of less than 100 mm Hg at 20° C.

4. The method of claim 1, wherein said precursor has a vapor pressure of 10-30 mm Hg at 20° C.

5. The method of claim 1, wherein said precursor comprises hexamethyldisiloxane of the formula

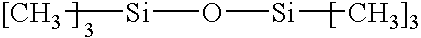

6. The method of claim 1, wherein said precursor comprises hexamethyldisilazane of the formula:

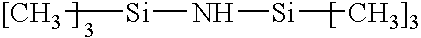

7. The method of claim 1, wherein said precursor comprises hexamethyldisilane having the formula:

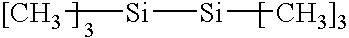

8. The method of claim 1, further including a reactive gas having a MW of less than 100.

9. The method of claim 8, wherein said reactive gas having a MW of less than 100 comprises nitrogen, methane, acetylene, oxygen, ammonia or combinations thereof.

10. A method for producing a coating on a substrate comprising:
depositing metal atoms on one or more surfaces of a substrate;
subjecting said metal atoms to a reactive gas, said reactive gas supplied from a precursor containing silicon, carbon and hydrogen, said precursor having a MW of greater than or equal to 100-400 and a vapor pressure of less than 100 mm Hg at 20° C.; and
producing a coating layer of a metal compound, wherein said metal compound comprises nanocrystals of a transition metal compound in a ceramic matrix, wherein said transition metal compound is selected from the group consisting of metal nitrides, metal carbides, metal silicides and combinations thereof.

11. The method of claim 10, wherein said precursor has a vapor pressure of 10-30 mm Hg at 20° C.

12. The method of claim 10, wherein said precursor comprises hexamethyldisiloxane of the formula

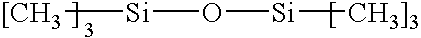

13. The method of claim 10, wherein said precursor comprises hexamethyldisilazane of the formula:

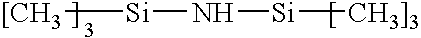

14. The method of claim 10, wherein said precursor comprises hexamethyldisilane having the formula:

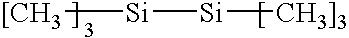

15. The method of claim 10, further including a reactive gas having a MW of less than 100.

16. The method of claim 15, wherein said reactive gas having a MW of less than 100 comprises nitrogen, methane, acetylene, oxygen, ammonia or combinations thereof.

17. A method for producing a coating on a substrate comprising:
depositing metal atoms on one or more surfaces of a substrate;
subjecting said metal atoms to an inert gas and to a reactive gas, said reactive gas supplied from a precursor containing silicon, carbon and hydrogen, said precursor having a MW of greater than or equal to 100-400 and a vapor pressure of less than 100 mm Hg at 20° C.; and
producing a coating layer of a metal of a transition metal and a coating layer of a metal compound, wherein said metal compound comprises nanocrystals of a transition metal compound in a ceramic matrix, wherein said transition metal compound is selected from the group consisting of metal nitrides, metal carbides, metal silicides and combinations thereof.

18. The method of claim 17, wherein said precursor has a vapor pressure of 10-30 mm Hg at 20° C.

19. The method of claim 17, wherein said precursor comprises hexamethyldisiloxane of the formula

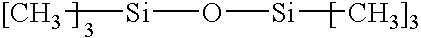

20. The method of claim 17, wherein said precursor comprises hexamethyldisilazane of the formula:

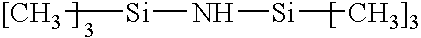

21. The method of claim 17, wherein said precursor comprises hexamethyldisilane having the formula:

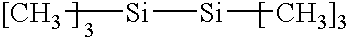

22. The method of claim 17, further including a reactive gas having a MW of less than 100.

23. The method of claim 22, wherein said reactive gas having a MW of less than 100 comprises nitrogen, methane, acetylene, oxygen, ammonia or combinations thereof.

24. The method of claim 17 comprising alternatively subjecting said metal atoms to an inert gas and to a reactive gas.
